(19) United States
(12) Patent Application Publication
(10) Pub. No.: US 2010/0080280 A1
(43) Pub. Date: Apr. 1, 2010

(54) DECISION FEEDBACK EQUALIZER WITH PARTIAL FEEDBACK EQUALIZER IN A VARIABLE SIDEBAND COMMUNICATIONS SYSTEM

(75) Inventors: Syang-Myau Hwang, Cupertino, CA (US); Lin Yang, Fremont, CA (US); Shue-Lee Chang, San Jose, CA (US); Jun Lu, Saratoga, CA (US)

Correspondence Address: FRANK F. TIAN, 331-4A THIRD AVENUE, LONG BEACH, NJ, 07740, US

(73) Assignee: LEGEND SILICON CORP., Fremont, CA (US)

(21) Appl. No.: 12/239,790

(22) Filed: Sep. 28, 2008

(51) Int. Cl. H03H 7/30; H03D 1/04

(52) U.S. Cl. 375/233; 375/346

(57) ABSTRACT

In a receiver of a multi-leveled variable sideband communications system, a method is provided that comprises the steps of: dividing the receiver into a real portion and a complex portion; and providing a decision feedback equalizer (DFE) processing data substantially in the real portion.

### CROSS-REFERENCE TO OTHER APPLICATIONS

The following applications of common assignee and filed on the same day herewith are related to the present application, and are herein incorporated by reference in their entireties:

U.S. patent application Ser. No. ______ with attorney docket number LSFFT-110.

U.S. patent application Ser. No. ______ with attorney docket number LSFFT-102.

U.S. patent application Ser. No. ______ with attorney docket number LSFFT-103.

U.S. patent application Ser. No. ______ with attorney docket number LSFFT-105.

U.S. patent application Ser. No. ______ with attorney docket number LSFFT-106.

U.S. patent application Ser. No. ______ with attorney docket number LSFFT-107.

### FIELD OF THE INVENTION

The present invention relates generally to digital filters, more specifically the present invention relates to a decision feedback equalizer (DFE) with a partial feedback equalizer (PFE).

### BACKGROUND

Electronic equipment and supporting software applications typically involve signal processing. For example, home theater, computer graphics, medical imaging and telecommunications all rely on signal-processing technology. Signal processing requires fast math in complex, but repetitive algorithms. Many applications require computations in real-time, i.e., the signal is a continuous function of time, which need be sampled and converted to digital, for numerical processing. A signal processor has to execute algorithms performing discrete computations on the samples as they arrive. The architecture of a digital signal processor (DSP) is optimized to handle such algorithms. The characteristics of a good signal processing engine typically may include fast, flexible arithmetic computation units, unconstrained data flow to and from the computation units, extended precision and dynamic range in the computation units, dual address generators, efficient program sequencing, and ease of programming.

An equalization algorithm to guarantee a stable performance in fast fading channels for the advanced television system committee (ATSC) digital television (DTV) systems is known. In channels with high Doppler shifts, the conventional equalizer shows severe performance degradation. The previous equalizer with long filter taps to overcome long delay profiles is not suitable for fast fading channels. IEEE Trans. on Consumer Electronics, Vol. 51, No. 3, pp. 803˜808, August 2005 to No-Ik Heo, et al describes an adaptive sparse equalizer to fast fading and long delay spread for ATSC DTV. It further proposes a sparse equalization algorithm that is robust to the multipaths with long delay profiles as well as fast fading by utilizing channel estimation and an equalizer initialization. Fast fading channels with high Doppler shifts can be compensated with an adaptive tap selection technique as well as variable step-sizes. Under the ATSC test channels, the proposed algorithm is analyzed and compared with the conventional equalizer.

Decision feedback equalizer is known. IEEE Trans. on Communication, Vol. 47, No. 6, pp. 927˜937, June 1999 to Ian J. Fevier, et al describes a reduced complexity decision feedback equalization for multipath channels with large delay spreads. In the publication, two modified decision feedback equalization (DFE) structures are presented for the efficient equalization of long sparse channels with strong precursor, such as those encountered in high-speed communications over multipath channels with large delay spread. Unlike the previously known DFE, these structures allow the channel's sparseness to be exploited by simple tap allocation, before the sparseness is degraded by feed forward filtering. Both structures yield large reductions in complexity while maintaining performance comparable to the conventional DFE, hence overcoming a key computational bottleneck when equalizers are implemented in hardware for speed. Fast channel estimate-based algorithms for computing the modified DFE coefficients are derived. Simulation results are presented for data rates and channel profiles of the type considered for the proposed North American high definition television (HDTV) terrestrial broadcast mode

Decision feedback equalizer and a partial feedback equalizer are both independently known. Therefore, it is desirous to improve digital filter circuit structure with decision feedback equalizer combined with a partial feedback equalizer for a VSB receiver.

### SUMMARY OF THE INVENTION

A decision feedback equalizer combined with a partial feedback equalizer for a VSB receiver is provided.

A decision feedback equalizer with a partial feedback equalizer for a multi-leveled VSB receiver is provided.

A decision feedback equalizer with a partial feedback equalizer for an 8-VSB receiver is provided.

In a receiver of a multi-leveled variable sideband communications system, a method is provided that comprises the steps of: dividing the receiver into a real portion and a complex portion; and providing a decision feedback equalizer (DFE) processing data substantially in the real portion.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of an equalizer structure in accordance with some embodiments of the invention.

FIG. 2 is flowchart in accordance with some embodiments of the invention.

FIG. 3A is a example of a channel condition in accordance with some embodiments of the invention.

FIG. 3B is a first experimental result relating FIG. 3A.

FIG. 3C is a second experimental result relating FIG. 3A.

FIG. 3D is a third experimental result relating FIG. 3A.

FIG. 3E is a fourth experimental result relating FIG. 3A.

FIG. 3F is a fifth experimental result relating FIG. 3A.

FIG. 4 is an example of a digital receiver in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a decision feedback equalizer combined with a partial feedback equalizer. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of using known sequences within the guard intervals being used for a decision feedback equalizer combined with a partial feedback equalizer. The non-processor circuits may include, but are not limited to, a radio receiver, a radio transmitter, signal drivers, clock circuits, power source circuits, and user input devices. As such, these functions may be interpreted as steps of a method to a decision feedback equalizer combined with a partial feedback equalizer. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

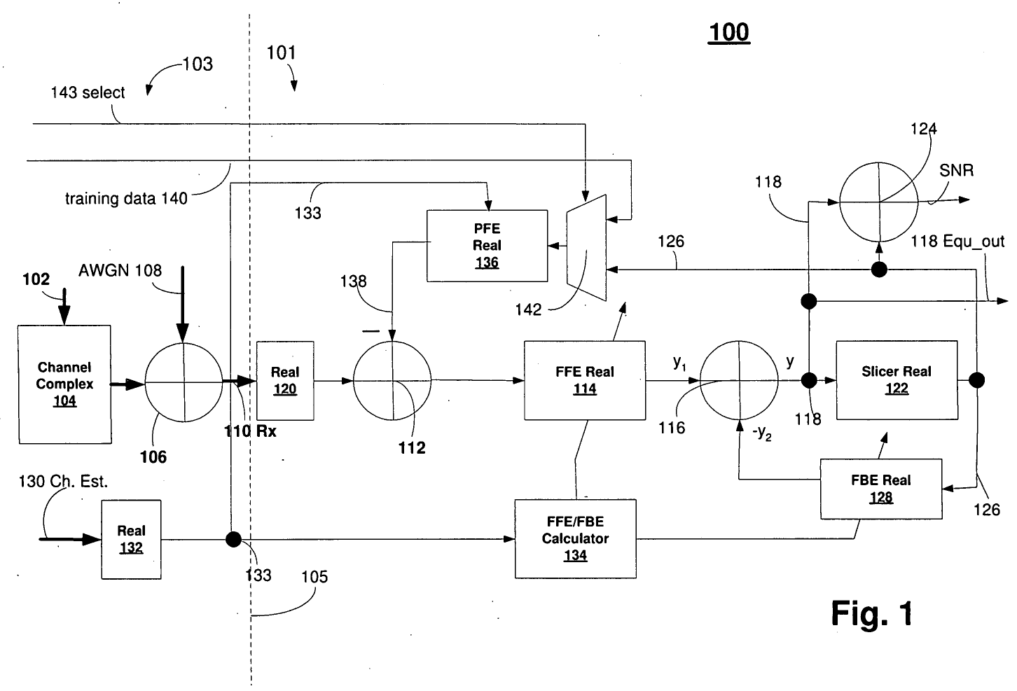

Referring to FIG. 1, a block diagram of a Decision Feedback Equalizer (DFE) 100 with Partial Feedback Equalizer (PFE) is shown. DFE 100 comprises a first portion 101 for real signal part processing and a second portion 103 for the typical complex signal comprising both real and imaginary parts. An imaginary broken line 105 roughly divides the first portion 101 and the second portion 103. Note that the complex signal paths are depicted in boldfaced or thick black lines, whereas the real signal paths are depicted in ordinary or thinner block lines.

Wireless transmitted data 102 are subjected to a set of channel limitations with additive white Gaussian noise (AWGN). This can be modeled as transmitted data 102 input into a channel complex 104. The output of the channel complex 104 is subjected to a first adder 106 that further receives an AWGN 108. The sum or the received data 110 of first adder 106 are further subjected to a first real part extractor 120 in which the real part of 110 is extracted. The extracted real part of the 110 is subjected to a second adder 112 that further receives the negative value of a second input 138 that is an output of a partial feedback equalizer (PFE) 136. In effect, the second adder 112 performs a subtraction action. The difference in turn is subjected to a programmable or controllable feed forward equalizer (FFE) 114. The output of FFE 114, y₁ is input into a third adder 116 and subtracted by an y₂. The difference 118, or y with y=y₁−y₂ is used in three ways. One, y is used as the equalizer DFE 100 output. Two, y is used as an input to a fourth adder 124. Three, y is used as an input to a slicer 122. Slicer 122 slices y and generates a sliced output 126. Sliced output 126 is used in three ways. One, sliced output 126 is used as the input to an programmable or adjustable feedback equalizer (FBE) 128. The output of FBE 128 is y₂. A FFE/FBE calculator 134 calculates and controls FBE 128 and FFE 114. Regarding the second use of sliced output 126, it acts as an input to fourth adder 124. Together with difference 118, fourth adder 124 generates the signal noise ratio (SNR) of the equalizer system. Turning now to the third use of sliced output 126, which acts as an input to a multiplexer (MUX) 142, MUX 142 is controlled by a select signal 143. MUX 142 has a second input, which is training data 140. The output of MUX 142 is used as the input to PFE 136.

To put FIG. 1 in another perspective, equalizer 100 can be divided into the first part 101 depicting the real realm, and the second part 103 depicting the complex realm. We will describe the second portion 103 first, and then, in turn, describe first portion 101. In second portion 103, transmitted data 102 are subjected to channel complex 104. The output of channel complex 104 in turn is subjected to an addition of AWGN 108 at first adder 106. The sum of first adder 106 is subjected to the first real part extractor 120 wherein the real part of the sum of first adder 106 is extracted for further processing in the real realm done stream. On another path of the second portion 103, the channel estimate information 130 is also having the real part extracted by a second real part extractor 132 for further processing in the real realm done stream.

In first portion 101, the extracted real part channel estimation information extracted real part channel estimation information 133 of second real part extractor 132 branches into two processing paths, a first path and a second path. In the first path, extracted real part channel estimation information 133 is used by FFE/FBE calculator 134 for the controlling or calibrating of both the FFE 114 and FBE 128. As can be seen, FBE 128 also receives sliced output 126 as the input thereto and outputs an y2 for further processing at 116. On the other hand, FFE 114 receives the difference from 112 as input thereto and outputs a calibrated y1 for 116 to derive y where y=y₁−y₂. The y, in turn, is used first, as the input to slicer 122; second y is used as the input to fourth adder 124 along with sliced output 126 to get a sum that is associated with signal noise ratio (SNR) of the system; and third, y is used as the output of equalizer 100.

In the second path, extracted real part channel estimation information 133 feeds into PFE 136 for generating 138 along with the output of MUX 142. MUX 142 receives two lines for multiplexing. A first line coming from training data 140, and a second line coming from sliced output 126. MUX 142 is controlled by the select signal 143. All the coefficients in FFE 114 and FBE 128 are real. Therefore the coefficients in PFE 136 are all real.

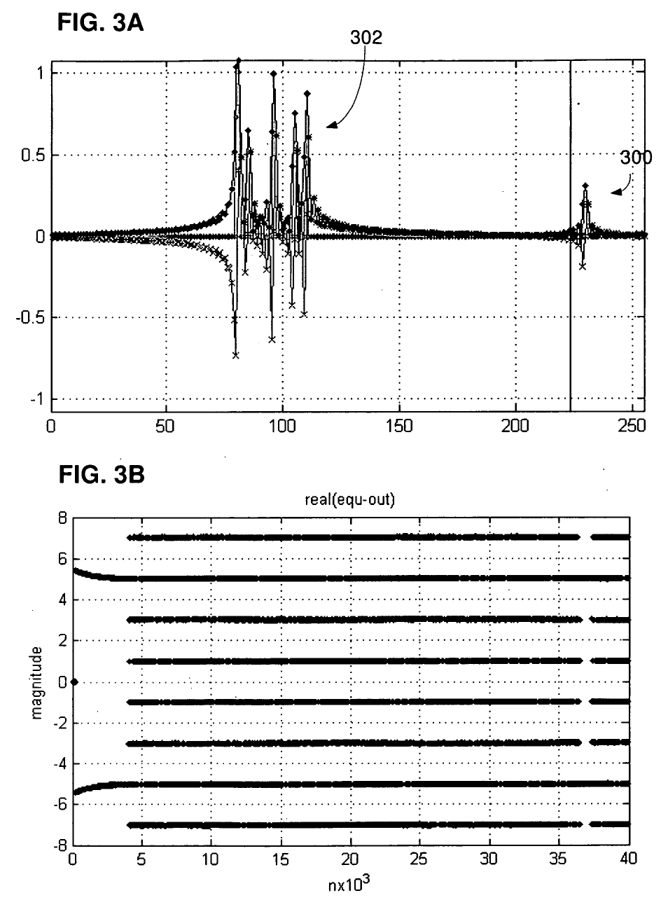

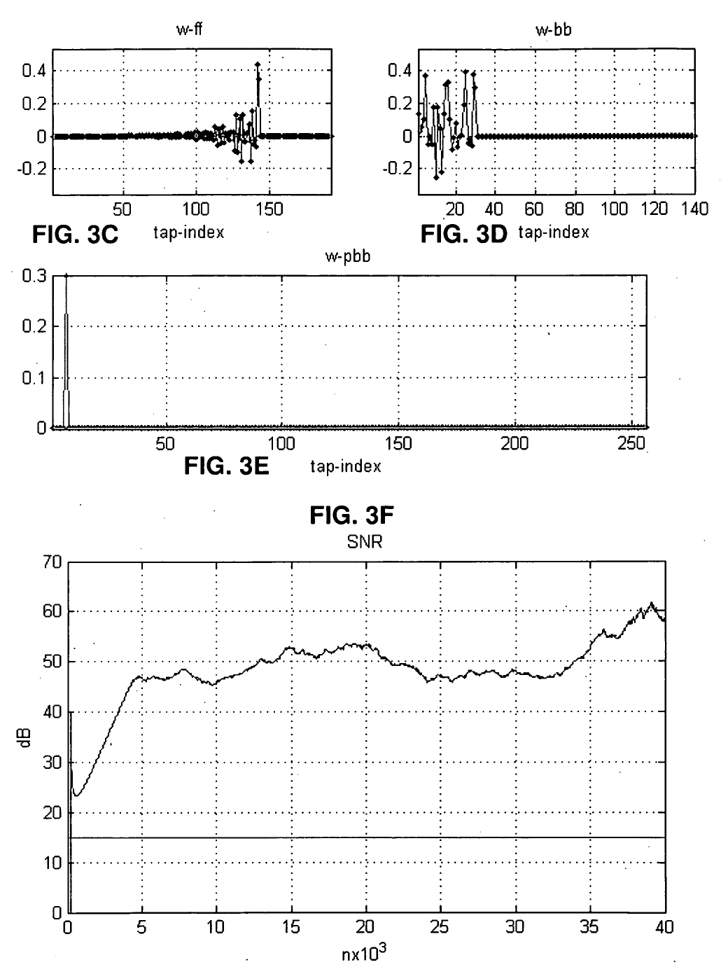

DEF 100 can provide optimal solutions subjected to a specific channel condition. But different with IEEE Trans. on Consumer Electronics, Vol. 51, No. 3, pp. 803˜808, August 2005 to No-Ik Heo, et al, the present invention's optimal solution can be use to equalize channels without performing the Least mean squares (LMS) algorithm. And in some VSB system such as the ATSC system, DFE 100 can have entirely real coefficients. Furthermore, the PFE 136 is used for channel-shortening purposes in that calculator 134 only calculates the real part of the shortened channel. In other words, PFE 136 takes care of the far echo 300 of FIG. 3A. This means that, if with correct channel estimation, PFE 136 can effectively cut channel length to satisfy the FFE/FBE pre/post-echo covered range as disclosed in IEEE Trans. on Communication, Vol. 47, No. 6, pp. 927˜937, June 1999 to Ian J. Fevier, et al. Further, see FIG. 3A infra.

The present invention provides a method that combines IEEE Trans. on Communication, Vol. 47, No. 6, pp. 927˜937, June 1999 to Ian J. Fevier, et al with the IEEE Trans. on Consumer Electronics, Vol. 51, No. 3, pp. 803˜808, August 2005 to No-Ik Heo, et al in a ATSC system.

An exemplified operation of FIG. 1 is as follows. Channel estimation information 130 has its real part extracted by real part extractor 132. The extracted information (still has the real part of a far echo), for example, may be as depicted in FIG. 3A but only maintaining its real part. The far echo part 300 of FIG. 3A is fed into PFE 136 and subtracted from the output of real part extractor 120 by adder 112. The sum of adder 112 is used for further process down stream of 100. The real part of the channel estimation information 133 minus the real part of the far echo part 300 of FIG. 3A is fed into FFE/FBE calculator 134, which calculates at least one set of coefficients for both FFE 114 and FBE 128.

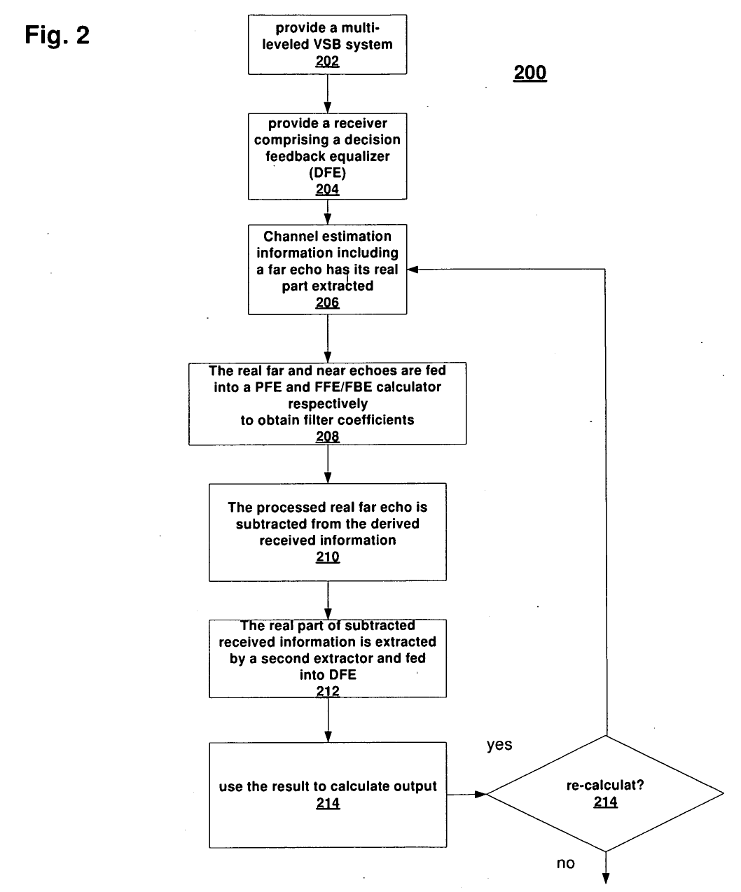

Referring to FIG. 2, a flowchart 200 depicting a method that combines a decision feedback equalizer (DFE) with a partial feedback equalizer (PFE) for data processing is shown. A multi-leveled VSB system as shown in FIG. 1 is provided (Step 202). A receiver comprising a decision feedback equalizer (DFE) is provided (Step 204). Channel estimation information including a far echo has its real part extracted (Step 206). The real portion of both a near echo and the far echo is fed is fed respectively into a PFE 136 and a FFE?FBE calculator 134 to obtain their respective coefficients (Step 208). The processed real far echo is subtracted from the the derived received information (Step 210). The real part of subtracted received information is extracted by a second extractor and fed into DFE 100 (Step 212). The result used to calculate the output of the DFE 100 (Step 214). Determine whether to re-calculate (Step 216). If re-calculate, the process 200 reverts back to step 206; otherwise process 200 ends.

Referring to FIG. 3A, an exemplified channel condition is shown. There is a far echo 300 of the equalizer channel response beyond a near echo 302. PFE 136 is applied here to shorten the channel in that far echo 300 is handled by the PFE 136 of FIG. 1 and the channel response without the far echo 300 is computed by calculator 134 also of FIG. 1. As described, calculator 134 only calculates in the real realm, there by simplifying computations. This can dramatically reduce the equalizer coefficient calculation complexity.

Referring to FIG. 3B, a test result of the present invention relating to a real equalizer output is shown. Note the smoothness of the output.

Referring to FIG. 3C, a test result of the present invention relating to coefficient characteristics of the FFE 114 of FIG. 1 is depicted.

Referring to FIG. 3D, a test result of the present invention relating to coefficient characteristics of the FBE 128 of FIG. 1 is depicted.

Referring to FIG. 3E, a test result of the present invention relating to coefficient characteristics of the PFE 136 of FIG. 1 is depicted.

Referring to FIG. 3F, a test result of the present invention relating to a signal noise ratio (SNR) is shown.

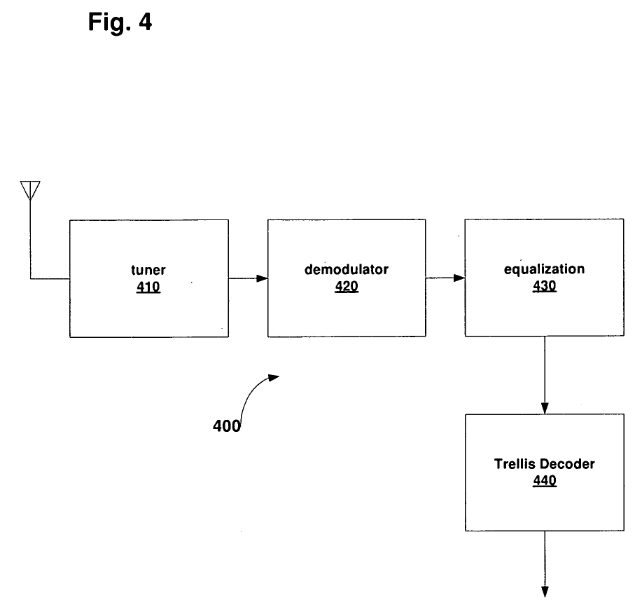

Referring to FIG. 4, a block diagram of a conventional digital television receiver 400, which can process a VSB signal, is shown. The digital television receiver 400 includes a tuner 410, a demodulator 420, an equalizer 430, and a TC M (Trellis-coded Modulation) decoder 440. TCM coding may use an error correction technique, which may improve system robustness against thermal noise. TCM decoding may have more robust performance ability and/or a simpler decoding algorithm. The output signal OUT of the TCM decoder 440 may be processed by a signal processor and output as multimedia signals (e.g., display signals and/or audio signals). The present invention is suitable for application in the equalizer 430. However, the present invention is not limited in its use in receiver 400. Other suitable applications are contemplated by the present invention as well.

The decision feedback equalizer (DFE) of the present invention may be a non-updated DFE.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. In a receiver of a multi-leveled variable sideband communications system, a method comprising the steps of:
dividing the receiver into a real portion and a complex portion; and
providing a decision feedback equalizer (DFE) processing data substantially in the real portion, wherein a calculator calculates at least one set of coefficients to control or calibrate a FFE or a FBE.

2. The method of claim 1, wherein the DFE comprises a partial feedback equalizer (PFE).

3. The method of claim 1 further comprising the step of using an extracted a portion of the real part of channel estimation information for inputting to the PFE.

4. The method of claim 1 further comprising the step of computing a first set of coefficients in PFE by using a real feed forward equalizer (FFE) coefficients and a real feed backward equalizer (FBE) coefficients.

5. The method of claim 4 further comprising the step of using an extracted real part of channel estimation information for inputting to a FFE/FBE calculator.

6. The method of claim 5 further comprising the step of Using the FFE/FBE calculator to control or calibrate the FFE and the FBE.

7. The method of claim 1 further comprising the step of Using and output of the DFE as an input to a slicer

8. The method of claim 7 further comprising the step of Use the sliced output as an input to an FBE.

9. The method of claim 1 is used in a VSB receiver.

10. The method of claim 1 is used in a 8-VSB receiver.

11. A receiver comprising a method comprising the steps of:
dividing the receiver into a real portion and a complex portion; and
providing a decision feedback equalizer (DFE) processing data substantially in the real portion, wherein a calculator calculates at least one set of coefficients to control or calibrate a FFE or a FBE.

12. The receiver of claim 11, wherein the DFE comprises a partial feedback equalizer (PFE).

13. The receiver of claim 11, wherein the method further comprising the step of using an extracted a portion of the real part of channel estimation information for inputting to the PFE.

14. The receiver of claim 11, wherein the method further comprising the step of computing a first set of coefficients in PFE by using a real feed forward equalizer (FFE) coefficients and a real feed backward equalizer (FBE) coefficients.

15. The receiver of claim 14, wherein the method further comprising the step of using an extracted real part of channel estimation information for inputting to a FFE/FBE calculator.

16. The receiver of claim 15, wherein the method further comprising the step of Using the FFE/FBE calculator to control or calibrate the FFE and the FBE.

17. The receiver of claim 11, wherein the method further comprising the step of Using and output of the DFE as an input to a slicer

18. The receiver of claim 17, wherein the method further comprising the step of Use the sliced output as an input to an FBE.

19. The receiver of claim 11 is a VSB receiver.

20. The used in of claim 11 is an 8-VSB receiver.
